(19) United States
(12) Patent Application Publication
(10) Pub. No.: US 2024/0250136 A1
(43) Pub. Date: Jul. 25, 2024

(54) BACKSIDE CONTACT WITH CONTACT JUMPER FOR STACKED FET

(71) Applicant: INTERNATIONAL BUSINESS MACHINES CORPORATION, Armonk, NY (US)

(72) Inventors: Ruilong Xie, Niskayuna, NY (US); Albert M. Chu, Nashua, NH (US); Lawrence A. Clevenger, Saratoga Springs, NY (US); Brent A. Anderson, Jericho, VT (US); Nicholas Anthony Lanzillo, Wynantskill, NY (US); Reinaldo Vega, Mahopac, NY (US)

(21) Appl. No.: 18/158,505

(22) Filed: Jan. 24, 2023

(51) Int. Cl. H01L 29/417; H01L 23/528; H01L 27/088; H01L 29/06; H01L 29/40; H01L 29/423; H01L 29/775

(52) U.S. Cl. CPC H01L 29/4175; H01L 23/5286; H01L 27/088; H01L 29/0673; H01L 29/401; H01L 29/42392; H01L 29/775

(57) ABSTRACT

A semiconductor structure is presented including backside contacts with jumpers and frontside back-end-of-line (BEOL) components electrically connected to the backside contacts by one or more deep via contacts. The jumpers electrically connect a plurality of source/drain (S/D) regions. At least one of the backside contacts is electrically connected to a backside power rail. At least one of the backside contacts has a first height and at least one of the backside contacts has a second height, where the second height is greater than the first height.

### BACKGROUND

The present invention relates generally to semiconductor devices, and more specifically, to constructing a self-aligned backside contact with a contact jumper for a stacked field effect transistor (FET).

Semiconductor devices are used in a variety of electronic applications, such as personal computers, cell phones, digital cameras, and other electronic equipment. Semiconductor devices are usually fabricated by sequentially depositing insulating or dielectric layers, conductive layers, and semiconductive layers of material over a semiconductor substrate, and patterning the various material layers using lithography to form circuit components and elements thereon.

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node. With the increased demands for miniaturization, higher speed, greater bandwidth, lower power consumption, and lower latency, chip layout has become more complicated and difficult to achieve in the production of semiconductor dies.

### SUMMARY

In accordance with an embodiment, a semiconductor structure is provided. The semiconductor structure includes backside contacts with jumpers and frontside back-end-of-line (BEOL) components electrically connected to the backside contacts by one or more deep via contacts.

In accordance with another embodiment, a semiconductor structure is provided. The semiconductor structure includes stacked field effect transistors (FETs), backside contacts with jumpers, and frontside back-end-of-line (BEOL) components electrically connected to the backside contacts by one or more deep via contacts.

In accordance with yet another embodiment, a method for forming a semiconductor structure is provided. The method includes forming a stacked field effect transistor (FET) over an etch stop layer placed over a substrate, recessing the etch stop layer to define trenches between the stacked FETs, depositing bottom epitaxial growth within the trenches, forming bottom source/drain (S/D) epi over the bottom epitaxial growth, forming top S/D epi over the bottom S/D epi, constructing remaining front-end-of-line (FEOL), middle-of-line (MOL), and back-end-of-line (BEOL) components, bonding a carrier wafer to the BEOL, flipping the wafer, removing the substrate and removing the etch stop layer selective to the bottom epitaxial growth, depositing an interlayer dielectric (ILD), and forming backside contacts with jumpers such that the BEOL components electrically connect to the backside contacts by one or more deep via contacts.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a cross-sectional view of a semiconductor structure including a first nanosheet stack and a second nanosheet stack formed over a substrate, where a sacrificial material is formed over the first and second nanosheet stacks, in accordance with an embodiment of the present invention;

FIG. 2 is a cross-sectional view of the semiconductor structure of FIG. 1 where sacrificial layers are selectively removed, in accordance with an embodiment of the present invention;

FIG. 3 is a cross-sectional view of the semiconductor structure of FIG. 2 where spacers, bottom dielectric isolation (BDI) and middle dielectric isolation (MDI) layers are formed, then the first and second nanosheet stacks are selectively recessed, and inner spacers are formed, in accordance with an embodiment of the present invention;

FIG. 4 is a cross-sectional view of the semiconductor structure of FIG. 3 where the BDI layer and the first sacrificial layer directly contacting the substrate are recessed to create trenches, in accordance with an embodiment of the present invention;

FIG. 5 is a cross-sectional view of the semiconductor structure of FIG. 4 where bottom epitaxial growth is deposited within the trenches, in accordance with an embodiment of the present invention;

FIG. 6 is a cross-sectional view of the semiconductor structure of FIG. 5 where a bottom source/drain (S/D) epi, a top S/D epi, and interlayer dielectric (ILD) are deposited, and where the sacrificial layers of the first and second nanosheet stacks are removed and replaced with a high-k metal gate (HKMG), in accordance with an embodiment of the present invention;

FIG. 7 is a cross-sectional view of the semiconductor structure of FIG. 6 where S/D contacts and gate contacts are formed, back-end-of-line (BEOL) processing is performed, and a carrier wafer is bonded to the BEOL, in accordance with an embodiment of the present invention;

FIG. 8 is a cross-sectional view of the semiconductor structure of FIG. 7 where the wafer is flipped, the substrate is selectively removed, and the shallow trench isolation (STI) regions are exposed, in accordance with an embodiment of the present invention;

FIG. 9 is a cross-sectional view of the semiconductor structure of FIG. 8 where the first sacrificial layer is selectively removed to expose the bottom epitaxial growth, in accordance with an embodiment of the present invention;

FIG. 10 is a cross-sectional view of the semiconductor structure of FIG. 9 where a backside ILD is deposited over the bottom epitaxial growth, in accordance with an embodiment of the present invention;

FIG. 11 is a cross-sectional view of the semiconductor structure of FIG. 10 where the backside ILD is patterned to expose a top surface of the bottom epitaxial growth, in accordance with an embodiment of the present invention;

FIG. 12 is a cross-sectional view of the semiconductor structure of FIG. 11 where a V-shaped recess takes place at the bottom epitaxial growth and backside contact metallization takes place, in accordance with an embodiment of the present invention;

FIG. 13 is a cross-sectional view of the semiconductor structure of FIG. 12 where a mask layer is formed to protect a backside contact which would extend to a backside interconnect, while exposed backside contact metallization is selectively recessed, in accordance with an embodiment of the present invention; and

FIG. 14 is a cross-sectional view of the semiconductor structure of FIG. 13 where backside power rail and backside power distribution network (BSPDN) formation takes place, in accordance with an embodiment of the present invention.

Throughout the drawings, same or similar reference numerals represent the same or similar elements.

### DETAILED DESCRIPTION

Embodiments in accordance with the present invention provide methods and devices for constructing a self-aligned backside contact with a contact jumper for a stacked field effect transistor (FET). Self-aligned backside contacts are needed to mitigate poor overlay margins at a backside of a wafer. A conventional placeholder approach to backside contact schemes, however, does not support contact jumpers. Backside contact jumpers are beneficial in connecting together several bottom source/drain (S/D) regions to the frontside of the wafer. The exemplary embodiments, by employing a backside contact with a contact jumper or gate jumper, can reduce frontside metal track usage, and, thus, potentially reduce cell height or free up more tracks for global routing. The gate jumpers connect several S/D regions together on the backside of the wafer.

Examples of semiconductor materials that can be used in forming such nanosheet structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

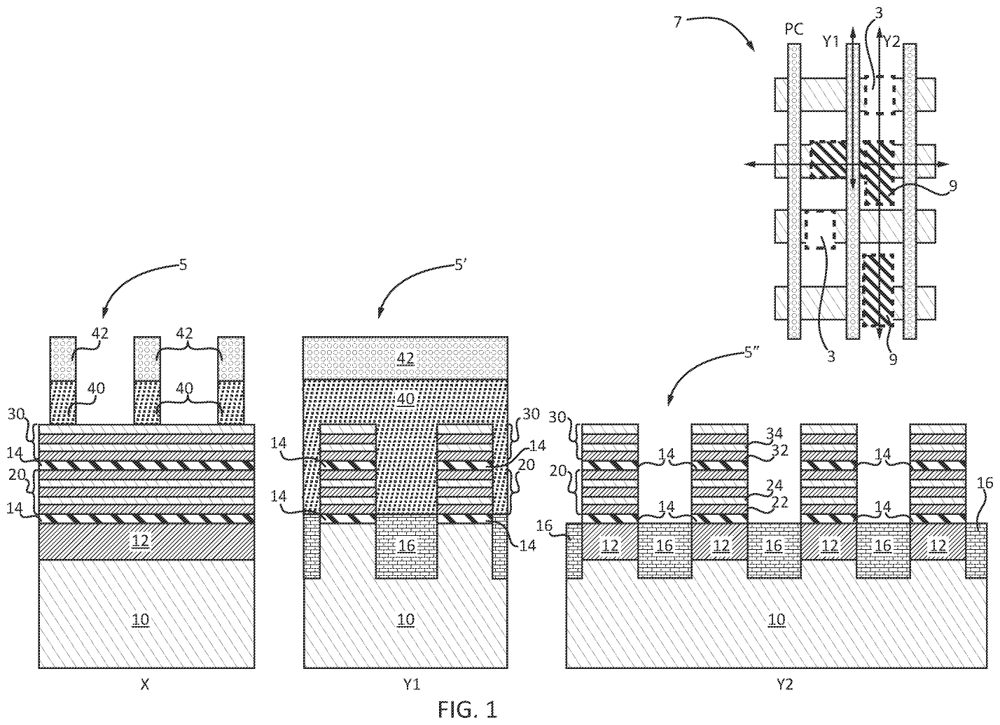

FIG. 1 is a cross-sectional view of a semiconductor structure including a first nanosheet stack and a second nanosheet stack formed over a substrate, where a sacrificial material is formed over the first and second nanosheet stacks, in accordance with an embodiment of the present invention.

In various example embodiments, in structure 5, a first nanosheet stack 20 is formed over a substrate 10. Structure 5 is a cross-sectional view along axis X (top view 7). A first sacrificial layer 12 and a second sacrificial layer 14 are positioned directly between the substrate 10 and the first nanosheet stack 20. The first sacrificial layer 12 can have a greater thickness than the second sacrificial layer 14. The first sacrificial layer 12 can be, e.g., a silicon germanium (SiGe) layer with a germanium concentration of 30%. The first sacrificial layer 12 can also be referred to as an etch stop layer.

The second sacrificial layer 14 can be, e.g., a SiGe layer with a germanium concentration of 55%. Additionally, a third sacrificial layer 14 is positioned directly between the first nanosheet stack 20 and the second nanosheet stack 30. The first and second nanosheet stacks 20, 30 are in a stacked configuration. A dummy gate 40 and a hardmask 42 are also deposited over the first and second nanosheet stacks 20, 30.

In structure 5′, which is a cross-sectional view along axis Y1 (top view 7), shallow trench isolation (STI) regions 16 are shown. The STI regions 16 rest in trenches formed within the substrate 10. The STI regions 16 are vertically offset from the first and second nanosheet stacks 20, 30.

In structure 5″, which is a cross-sectional view along axis Y2 (top view 7), a relationship between the first and second nanosheet stacks 20, 30 and the STI regions 16 is shown.

The top view 7 further illustrates the layout positions of a deep direct backside contact (DBC 3) and a shallow DBC 9, which will be formed in later process steps.

The first nanosheet stack 20 includes alternating layers of a first semiconductor material (or layer) 22 and a second semiconductor material (or layer) 24. The first semiconductor material 22 can be, e.g., silicon germanium (SiGe) and the second semiconductor material 24 can be, e.g., silicon (Si).

The second nanosheet stack 30 includes alternating layers of a first semiconductor material (or layer) 32 and a second semiconductor material (or layer) 34. The first semiconductor material 32 can be, e.g., silicon germanium (SiGe) and the second semiconductor material 34 can be, e.g., silicon (Si).

In one or more embodiments, the substrate 10 can be a semiconductor or an insulator with an active surface semiconductor layer. The substrate 10 can be crystalline, semi-crystalline, microcrystalline, or amorphous. The substrate 10 can be essentially (e.g., except for contaminants) a single element (e.g., silicon), primarily (e.g., with doping) of a single element, for example, silicon (Si) or germanium (Ge), or the substrate 10 can include a compound, for example, Al₂O₃, SiO₂, GaAs, SiC, or SiGe. The substrate 10 can also have multiple material layers, for example, a semiconductor-on-insulator substrate (SeOI), a silicon-on-insulator substrate (SOI), germanium-on-insulator substrate (GeOI), or silicon-germanium-on-insulator substrate (SGOI). The substrate 10 can also have other layers forming the substrate 10, including high-k oxides and/or nitrides. In one or more embodiments, the substrate 10 can be a silicon wafer. In an embodiment, the substrate 10 is a single crystal silicon wafer.

Referring to, e.g., the first nanosheet stack 20, the first semiconductor material 22 can be the first layer in a stack of sheets of alternating materials. The first nanosheet stack 20 thus includes first semiconductor materials (or layers) 22 and second semiconductor materials (or layers) 24.

Referring to, e.g., the second nanosheet stack 30, the first semiconductor material 32 can be the first layer in a stack of sheets of alternating materials. The second nanosheet stack 30 thus includes first semiconductor materials (or layers) 32 and second semiconductor materials (or layers) 34.

Although it is specifically contemplated that the first semiconductor materials 22/32 can be formed from silicon germanium and that the second semiconductor materials 24/34 can be formed from silicon, it should be understood that any appropriate materials can be used instead, as long as the two semiconductor materials have etch selectivity with respect to one another. As used herein, the term “selective” in reference to a material removal process denotes that the rate of material removal for a first material is greater than the rate of removal for at least another material of the structure to which the material removal process is being applied. The alternating semiconductor materials 22/24 (or 32/34) can be deposited by any appropriate mechanism. It is specifically contemplated that the first and second semiconductor materials 22/24 (or 32/34) can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

Regarding various dielectrics or dielectric layers (e.g., the hardmask 42) discussed herein, the dielectrics can include, but are not limited to, SiN, SiOCN, SiOC, SiBCN, SiO, SO₂, or ultra-low-k (ULK) materials, such as, for example, porous silicates, carbon doped oxides, silicon dioxides, silicon nitrides, silicon oxynitrides, carbon-doped silicon oxide (SiCOH) and porous variants thereof, silsesquioxanes, siloxanes, or other dielectric materials having, for example, a dielectric constant in the range of about 2 to about 10.

In some embodiments, the dielectrics can be conformally deposited using atomic layer deposition (ALD) or, chemical vapor deposition (CVD). Variations of CVD processes suitable for forming the dielectrics include, but are not limited to, Atmospheric Pressure CVD (APCVD), Low Pressure CVD (LPCVD) and Plasma Enhanced CVD (PECVD), Metal-Organic CVD (MOCVD) and combinations thereof can also be employed.

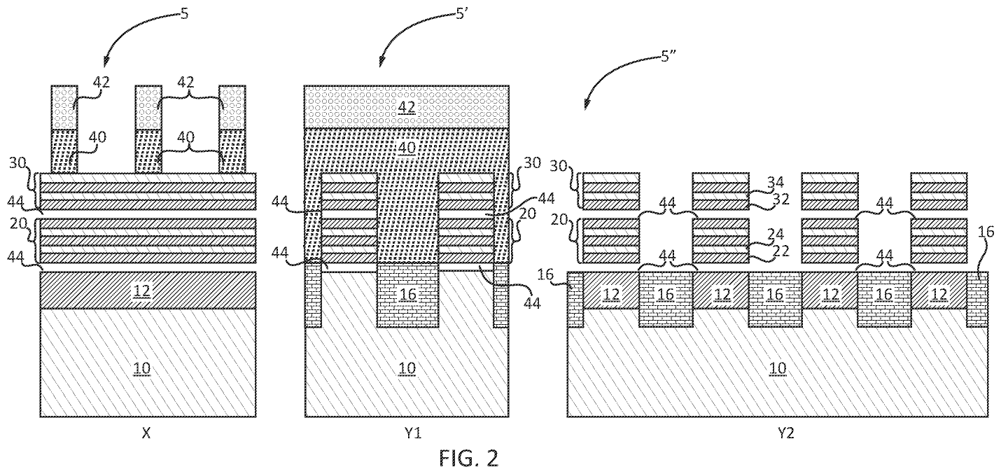

FIG. 2 is a cross-sectional view of the semiconductor structure of FIG. 1 where sacrificial layers are selectively removed, in accordance with an embodiment of the present invention.

In various example embodiments, the second and third sacrificial layers 14 are selectively removed to form openings 44. The openings 44 separate the first nanosheet stack 20 from the second nanosheet stack 30, and further separate the first sacrificial layer 12 from the first nanosheet stack 20. The second and third sacrificial layers 14 are shown removed in cross-sectionals views 5, 5′, and 5″.

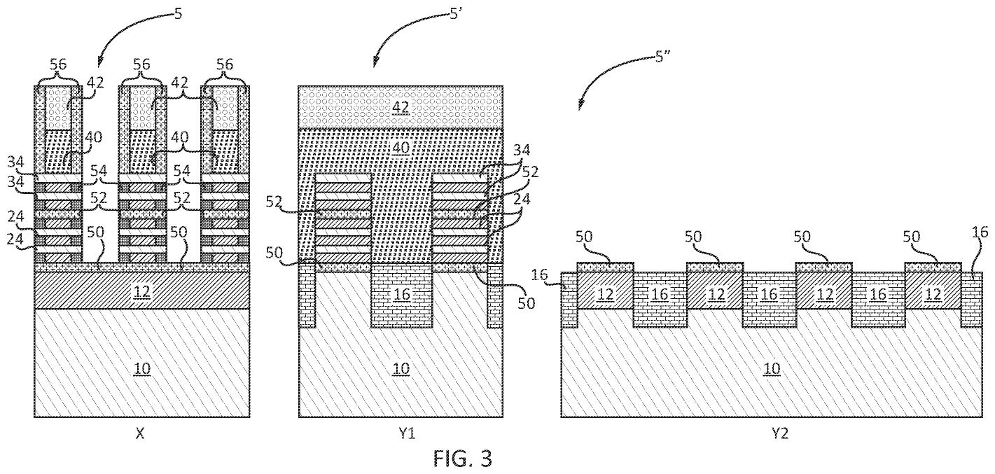

FIG. 3 is a cross-sectional view of the semiconductor structure of FIG. 2 where spacers, bottom dielectric isolation (BDI) and middle dielectric isolation (MDI) layers are formed, then the first and second nanosheet stacks are selectively recessed, and inner spacers are formed, in accordance with an embodiment of the present invention.

In various example embodiments, the spacers 56, and the bottom dielectric isolation (BDI) 50 and middle dielectric isolation (MDI) layers 52 are formed by a conformal dielectric deposition followed by an anisotropic spacer reactive ion etch (RIE) process. After that, the first and second nanosheet stacks 20, 30 are selectively recessed, followed by SiGe indentation, and inner spacers 54 are formed. The BDI layer 50 directly contacts an entirety of a top surface of the first sacrificial layer 12. The MDI layer 52 is positioned directly between the first and second nanosheet stacks 20, 30. Additionally, spacers 56 are formed adjacent the dummy gate 40 and the hardmask 42.

The inner spacers 54 can include any of one or more of SiN, SiBN, SiCN and/or SiBCN films.

The spacers 56 can include any of one or more of SiN, SiBN, SiCN and/or SiBCN films.

The etching can include a dry etching process such as, for example, reactive ion etching, plasma etching, ion etching or laser ablation. The etching can further include a wet chemical etching process in which one or more chemical etchants are used to remove portions of the blanket layers that are not protected by the patterned photoresist.

The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include Tetrafluoromethane (CF₄), nitrogen trifluoride (NF₃), sulfur hexafluoride (SF₆), and helium (He), and Chlorine trifluoride (ClF₃). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF₄), and gas mixture with hydrogen (H₂). Chemical vapor etching can be performed by CVD with suitable pressure and temperature.

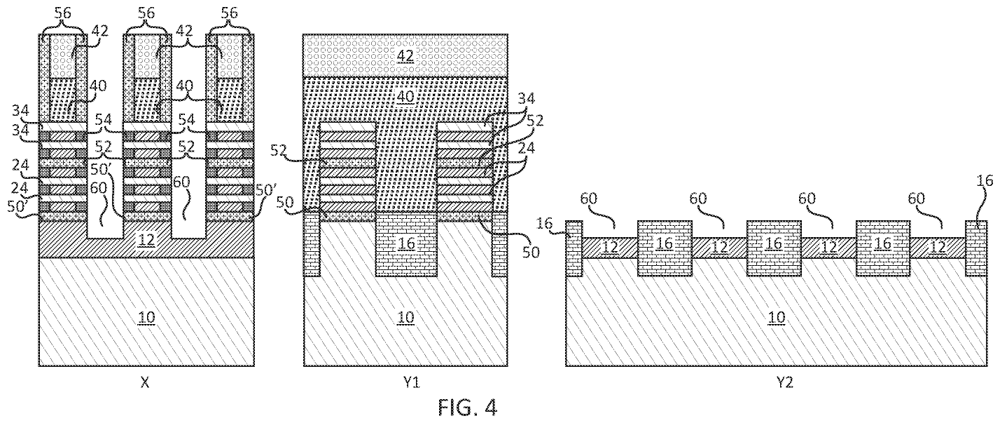

FIG. 4 is a cross-sectional view of the semiconductor structure of FIG. 3 where the BDI layer and the first sacrificial layer directly contacting the substrate are recessed to create trenches, in accordance with an embodiment of the present invention.

In various example embodiments, the BDI layer 50 and the first sacrificial layer 12 directly contacting the substrate 10 are recessed to create trenches 60. The etching of the BDI layer 50 results in BDI sections 50′ being formed in the X-view.

Cross-sectional view along axis Y2 illustrates the first sacrificial layer 12 recessed such that the STI regions 16 extend above the top surface of the first sacrificial layer 12. No changes are illustrated in the cross-sectional view along axis Y1.

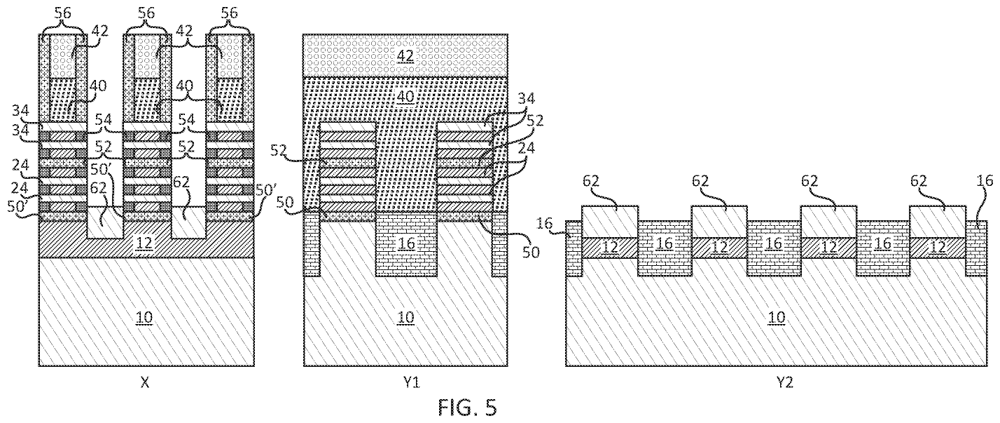

FIG. 5 is a cross-sectional view of the semiconductor structure of FIG. 4 where bottom epitaxial growth is deposited within the trenches, in accordance with an embodiment of the present invention.

In various example embodiments, bottom epitaxial growth 62 is deposited within the trenches 60. The bottom epitaxial growth 62 directly contacts sidewalls of the BDI sections 50′ and at least one inner spacer 54 in the X-view. Examples of the bottom epitaxial growth 62 can be SiGe with different Ge concentration than the etch stop layer 12, or III-V materials. Alternatively, the bottom epitaxial growth 62 can be formed through deposition and recess, such as TiO₂, AlOx, AlNx, etc.

The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

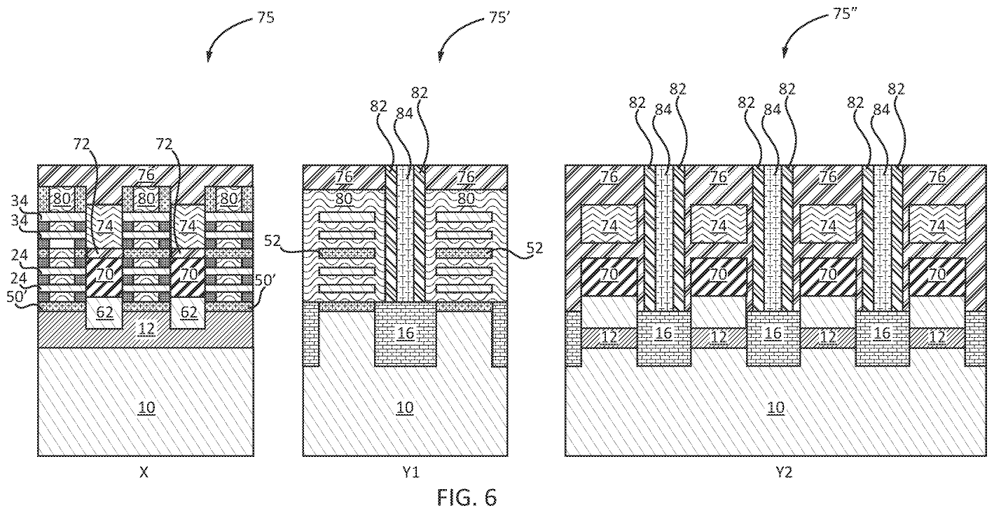

FIG. 6 is a cross-sectional view of the semiconductor structure of FIG. 5 where a bottom source/drain (S/D) epi, a top S/D epi, and interlayer dielectric (ILD) are deposited, and where the sacrificial layers of the first and second nanosheet stacks are removed and replaced with a high-k metal gate (HKMG), in accordance with an embodiment of the present invention.

In various example embodiments, in structure 75, a bottom S/D epi 70, a top S/D epi 74, and interlayer dielectric (ILD) 76 are deposited. The bottom S/D epi 70 is separated from the top S/D epi 74 by a dielectric layer 72 (which can be the same material as ILD 76). The bottom S/D epi 70 directly contacts the bottom epitaxial growth 62. Sidewalls of the bottom S/D epi 70 directly contact sidewalls of the inner spacers 54 associated with the first nanosheet stack 20 and sidewalls of the top S/D epi 74 directly contact sidewalls of the inner spacers 54 associated with the second nanosheet stack 30. Moreover, the sacrificial layers of the first and second nanosheet stacks 20, 30 are removed (e.g., the SiGe layers) and replaced with a high-k metal gate (HKMG) 80.

In structure 75′, the HKMG 80 and the ILD 76 between different stacked FET complementary metal oxide semiconductor (CMOS) cells are cut by a late gate cut process using conventional lithography and RIE processes. After gate cut openings are formed, first dielectric layers 82 are formed adjacent the HKMG 80 and a second dielectric layer 84 is formed directly between the first dielectric layers 82. The first and second dielectric layers 82, 84 are formed after a gate cut is performed. The second dielectric layer 84 has a thickness greater than the thickness of the first dielectric layers 82. The first and second dielectric layers 82, 84 are vertically aligned with the STI region 16. The HKMG 80 surrounds the Si layers (24/34) of the first and second nanosheet stacks 20, 30. The HKMG 80 further surrounds the MDI layer 52.

In structure 75″, the relationship between the bottom S/D epi 70, the top S/D epi 74, and the bottom epitaxial growth 62 is shown. Additionally, the relationship between the first dielectric layers 82, the second dielectric layer 84, and the STI region 16 is shown.

The bottom S/D epi 70 can also be referred to as a bottom epitaxy region and the top S/D epi 74 can be referred to as a top epitaxy region.

The bottom S/D epi 70 can be of the same or different materials for pFET and nFET devices, and can be either in-situ doped with appropriate polarity dopants (B for pFET and P for nFET devices) or doped by ion implantation.

The first dielectric layers 82 can be, e.g., SiN layers and the second dielectric layer 84 can be, e.g., SiO layers.

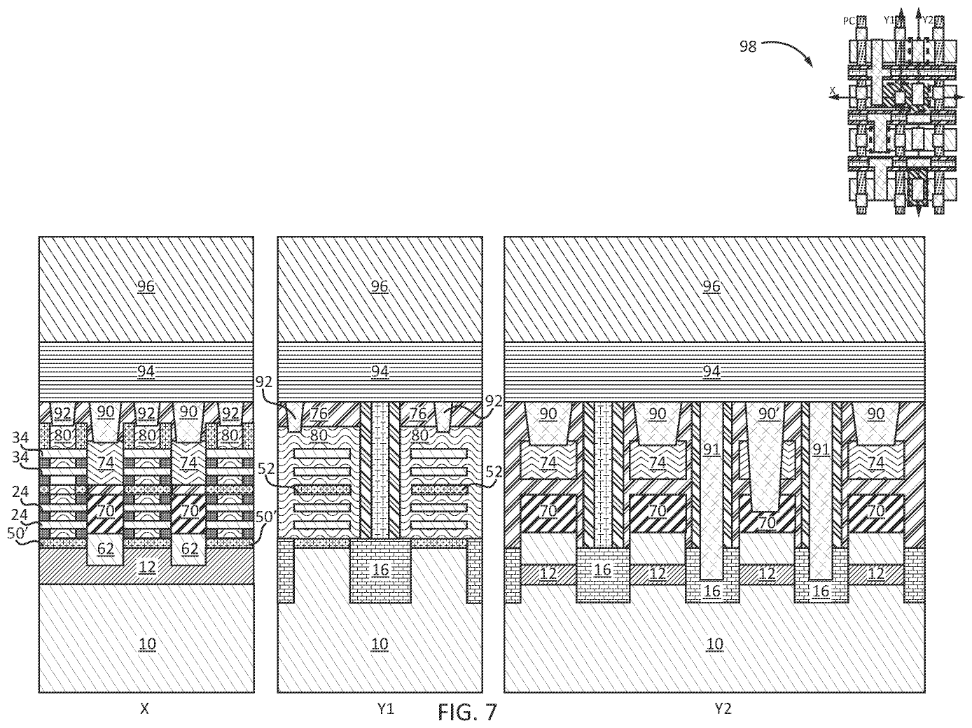

FIG. 7 is a cross-sectional view of the semiconductor structure of FIG. 6 where S/D contacts and gate contacts are formed, back-end-of-line (BEOL) processing is performed, and a carrier wafer is bonded to the BEOL, in accordance with an embodiment of the present invention.

In various example embodiments, in the X-view, S/D contacts 90 and gate contacts 92 are formed, back-end-of-line (BEOL) processing is performed, and a carrier wafer 96 is bonded to the BEOL 94. The S/D contacts 90 can also be referred to as CA contacts, whereas the gate contacts 92 can also be referred to as CB contacts. The S/D contacts 90 directly contact the top S/D epi 74 whereas the gate contacts 92 directly contact the HKMG 80.

In the Y1-view, the gate contacts 92 directly contact the HKMG 80.

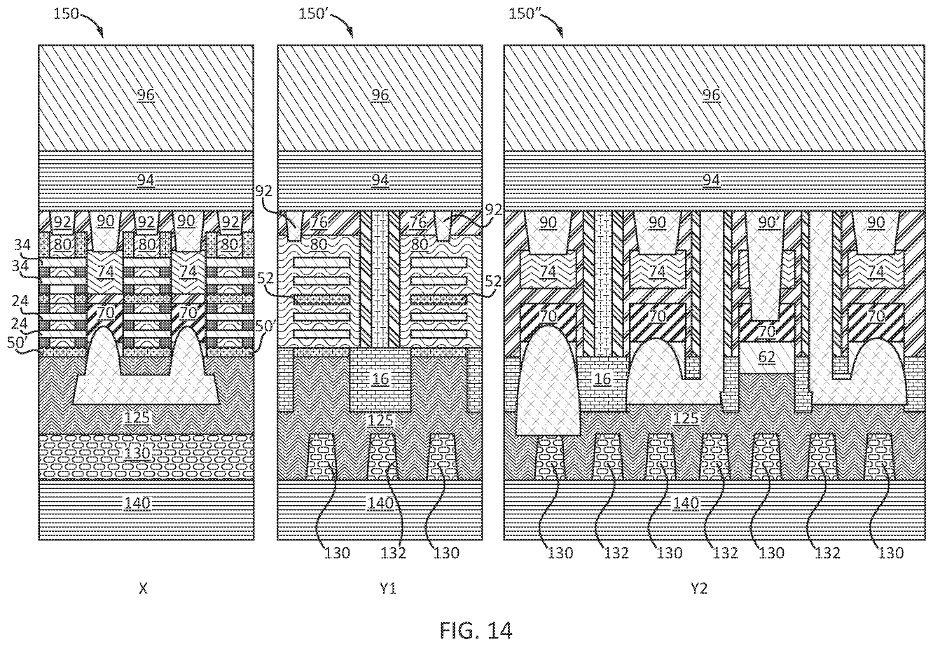

In the Y2-view, at least one S/D contact 90 directly contacts the top S/D epi 74 and at least one S/D contact 90 directly contacts both the top S/D epi 74 and the bottom S/D epi 70. Additionally at least two deep via contacts 91 are formed. The deep via contacts 91 directly contact sidewalls of the first dielectric layers 82 and extend into the STI regions 16. The deep via contacts 91 extend beyond a bottom surface of the bottom S/D epi 70. The deep via contacts 91 are vertically offset from the bottom S/D epi 70 and the top S/D epi 74. The deep via contacts 91 have a length greater than a length of all the S/D contact 90. The deep via contacts 91 electrically connect the BEOL 94 to the subsequently formed back contacts (FIG. 14).

Non-limiting examples of suitable conductive materials for the S/D contacts 90, the gate contacts 92, and the deep via contacts 91 include a silicide liner such as Ti, Ni, NiPt, etc., an adhesion metal liner, such as TiN, TaN, and conductive metal fill, such as Al, W, Co, Ru, etc. The conductive material can further include dopants that are incorporated during or after deposition. The conductive metal can be deposited by a suitable deposition process, for example, CVD, PECVD, PVD, plating, thermal or e-beam evaporation, and sputtering.

The high-k metal gate material of the RMGs (the HKMG 80) can be deposited by any suitable techniques, such as ALD, CVD, metal-organic CVD (MOCVD), physical vapor deposition (PVD), thermal oxidation, combinations thereof, or other suitable techniques. The RMGs can include a gate dielectric layer, e.g., HfO₂, LaO, AlO, ZrO, TiO, Ta₂O₅, Y₂O₃, SrTiO₃(STO), BaTiO₃(BTO), BaZrO, HfZrO, HfLaO, HfSiO, LaSiO, AlSiO, HfTaO, HfTiO, (Ba,Sr)TiO₃(BST), Al₂O₃, Si₃N₄, oxynitrides (SiON), or other suitable materials. The RMGs further include work function metals (WFMs), such as TiN, TiC, TiAl, TiAlC, etc., and conductive metal fills such as W, Al, or Ru.

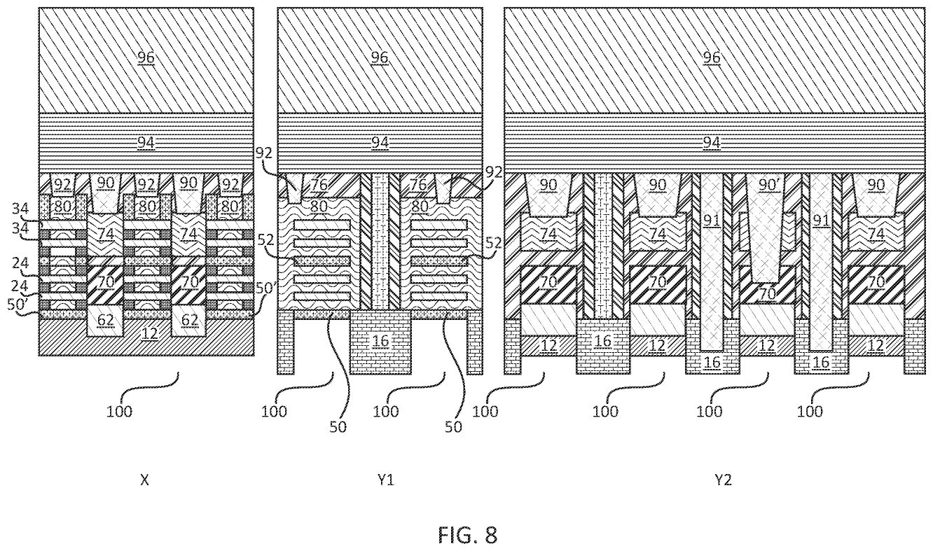

FIG. 8 is a cross-sectional view of the semiconductor structure of FIG. 7 where the wafer is flipped, the substrate is selectively removed, and the shallow trench isolation (STI) regions are exposed, in accordance with an embodiment of the present invention.

In various example embodiments, the wafer is flipped, the substrate 10 is selectively removed, and the shallow trench isolation (STI) regions 16 are exposed. In the X-view and the Y2-view, the first sacrificial layer 12 is also exposed. The removal of the substrate 10 results in openings 100. In the Y1-view, the BDI layer 50 is also exposed.

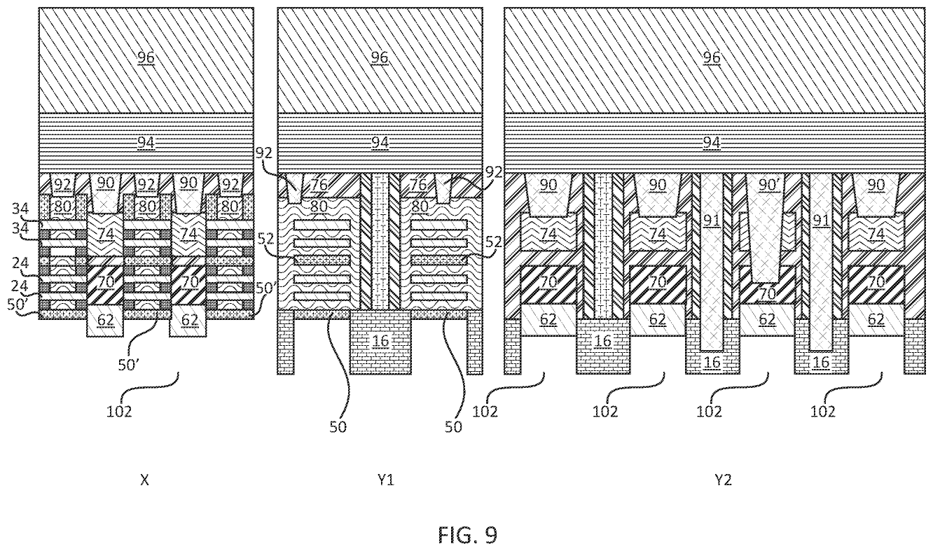

FIG. 9 is a cross-sectional view of the semiconductor structure of FIG. 8 where the first sacrificial layer is selectively removed to expose the bottom epitaxial growth, in accordance with an embodiment of the present invention.

In various example embodiments, the first sacrificial layer 12 is selectively removed to expose the bottom epitaxial growth 62 in the X-view and the Y2-view. The removal of the first sacrificial layer 12 results in openings 102.

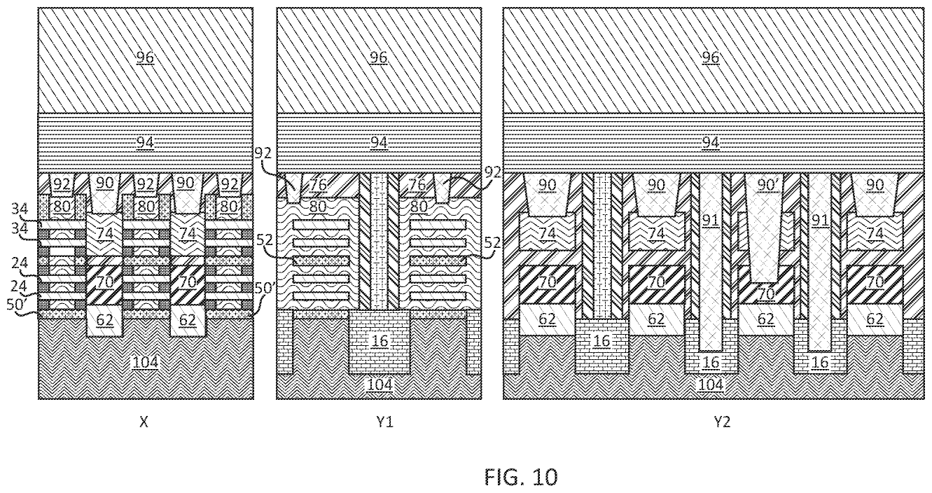

FIG. 10 is a cross-sectional view of the semiconductor structure of FIG. 9 where a backside ILD is deposited over the bottom epitaxial growth, in accordance with an embodiment of the present invention.

In various example embodiments, a backside ILD 104 is deposited over the bottom epitaxial growth 62. In the Y1-view, the backside ILD 104 directly contacts the STI regions 16, as well as the BDI layer 50.

The backside ILD 104 can be any suitable material, such as, for example, porous silicates, carbon doped oxides, silicon dioxides, silicon nitrides, silicon oxynitrides, or other dielectric materials. Any known manner of forming the backside ILD 104 can be utilized. The backside ILD 104 can be formed using, for example, CVD, PECVD, ALD, flowable CVD, spin-on dielectrics, or PVD.

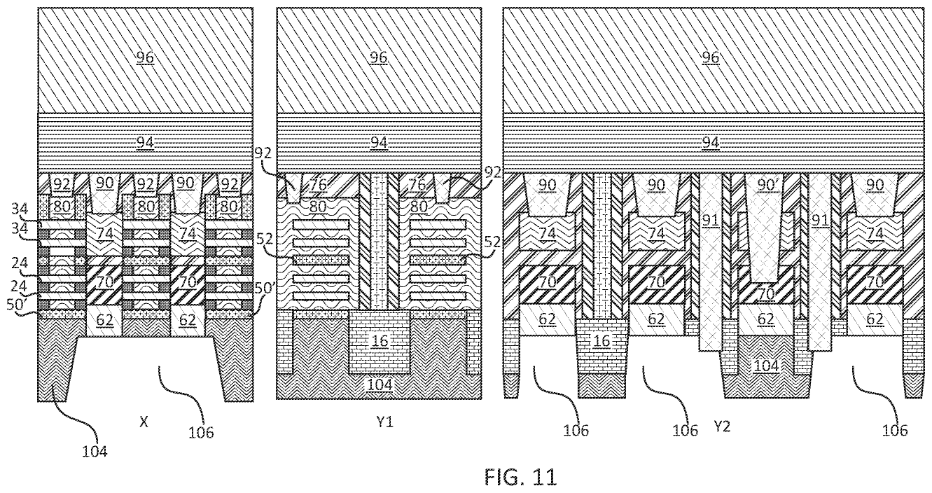

FIG. 11 is a cross-sectional view of the semiconductor structure of FIG. 10 where the backside ILD is patterned to expose a top surface of the bottom epitaxial growth, in accordance with an embodiment of the present invention.

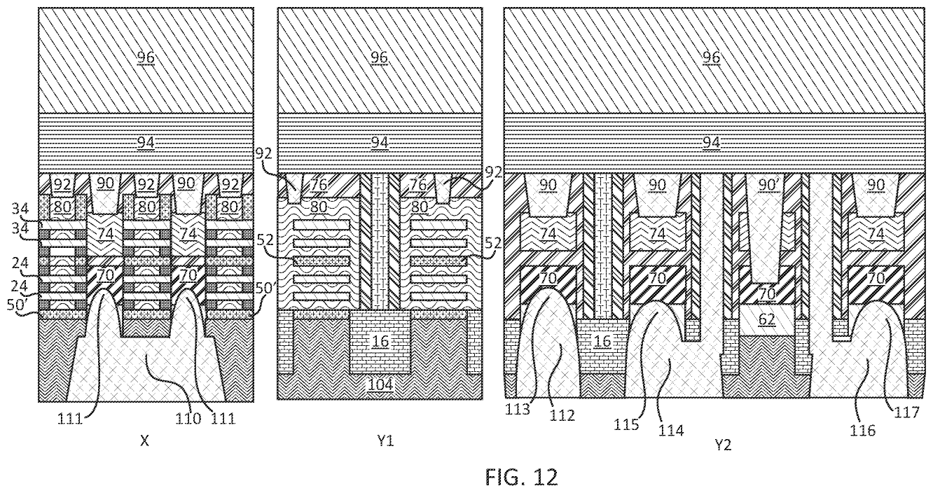

In various example embodiments, the backside ILD 104 is patterned to expose a top surface of the bottom epitaxial growth 62. The patterning results in openings 106 being formed. It is noted that a benefit of performing patterning at this phase is that the CA contacts (or S/D contacts 90) do not need to etch deep to contact the BDI layer 50 or the BDI sections 50′. This enables a CA jumper (FIG. 12) without shorting to PC.

FIG. 12 is a cross-sectional view of the semiconductor structure of FIG. 11 where a V-shaped (or U-shape) recess takes place at the bottom epitaxial growth and backside contact metallization takes place, in accordance with an embodiment of the present invention.

In various example embodiments, a V-shaped recess takes place at the bottom epitaxial growth 62 and backside contact metallization takes place. The recess can also be a U-shaped recess or a substantially curved recess.

In the X-view, the metallization 110 includes extensions or projections 111 that extend into the bottom epitaxial growth 62. The projections 111 are vertically aligned with the bottom S/D epi 70 and the top S/D epi 74. The metallization 110 can be referred to as a backside contact (BSCA). The projections 111 can also be referred to as gate jumpers. The jumpers are not vias or wires. The jumpers are thick metal connections.

In the Y1-view, metallization is not visible.

In the Y2-view, the metallization can be split into three regions, that is, a first metallization region 112, a second metallization region 114, and a third metallization region 116. The first metallization region 112 has a convex area 113 extending into the bottom S/D epi 70. The second metallization region 114 has a convex area 115 extending into the bottom S/D epi 70. The third metallization region 116 has a convex area 117 extending into the bottom S/D epi 70. The second metallization region 114 intersects with a deep via contact 91. Similarly, the third metallization region 116 intersects with another deep via contact 91. The first metallization region 112, the second metallization region 114, and the third metallization region 116 can be referred to as backside contacts (BSCA). The convex areas 113, 115, 117 can be referred to as gate jumpers. The convex areas 113, 115, 117 extend outwardly toward the bottom S/D epi 70.

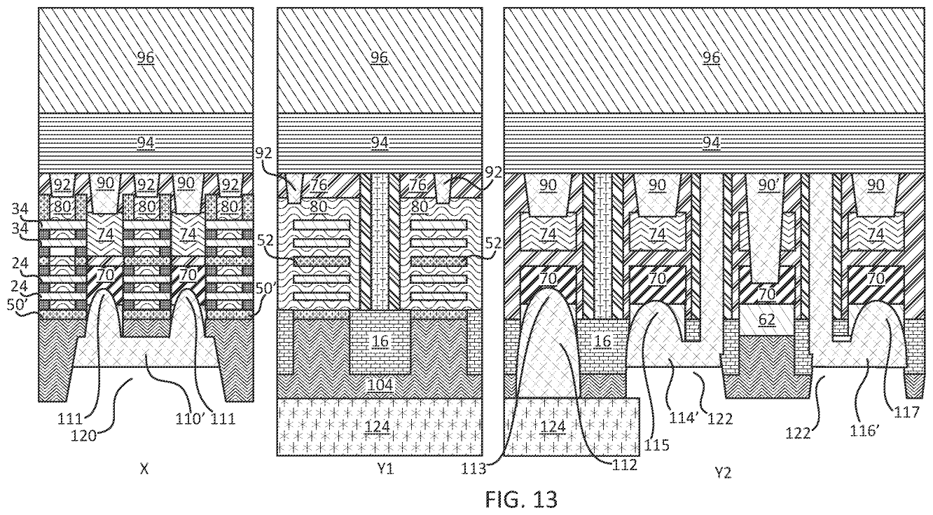

FIG. 13 is a cross-sectional view of the semiconductor structure of FIG. 12 where a mask layer 124 (such as an organic planarization layer (OPL)) is formed to protect a backside contact which would extend to a backside interconnect, while exposed backside contact metallization is selectively recessed, in accordance with an embodiment of the present invention.

In the X-view, the metallization 110 is now a recessed metallization 110′ with an opening 120 defined between portions of the backside ILD 104.

In the Y1-view, the OPL 124 is shown and the backside ILD 104 has not been recessed.

In the Y2-view, the second metallization 114 is now a recessed metallization 114′ with an opening 122 defined between portions of the backside ILD 104 and the third metallization 116 is now a recessed metallization 116′ with an opening 122 defined between portions of the backside ILD 104. The OPL 124 is visible on the left-hand side where the first metallization 122 is positioned. The recessed metallization 114′ and the recessed metallization 116′ still directly contact their respective deep via contacts 91.

The OPL 124 can include an organic material, such as a polymer. The thickness of the OPL 124 can be in a range from about 10 nm to about 300 nm. In one example, the thickness of the OPL 124 is about 100 nm-150 nm.

FIG. 14 is a cross-sectional view of the semiconductor structure of FIG. 13 where backside power rail and backside power distribution network (BSPDN) formation takes place, in accordance with an embodiment of the present invention.

In various example embodiments, further ILD 125 is deposited, VSS power rail (130) and VDD power rail (132) are formed, and a backside power distribution network (BSPDN) 140 are formed.

Structure 150 illustrates a gate jumper in the X-view.

Structure 150′ does not illustrate any gate jumpers in the Y1-view.

Structure 150″ does not illustrate any gate jumpers in the in the Y2-view.

The gate jumpers connect several S/D regions together on the backside of the wafer.

Stated differently, the semiconductor structure includes backside contacts with jumpers and frontside back-end-of-line (BEOL) components electrically connected to the backside contacts by one or more deep via contacts. The jumpers electrically connect a plurality of source/drain (S/D) regions. At least one of the backside contacts is electrically connected to a backside power rail. At least one of the backside contacts is electrically connected to a backside power delivery network (BSPDN). At least one of the backside contacts has a first height and at least one of the backside contacts has a second height, where the second height is greater than the first height. The jumpers have a substantially convex shape or curved shape or semi-circular shape. The jumpers are vertically aligned with a plurality of bottom S/D regions and a plurality of top S/D regions. The semiconductor structure further includes stacked field effect transistors (FETs). The stacked FETs are vertically offset from the jumpers.

In conclusion, the exemplary embodiments of the present invention present methods and devices for constructing a self-aligned backside contact with a contact jumper for a stacked FET. Self-aligned backside contacts are needed to mitigate poor overlay margins at a backside of a wafer. A conventional placeholder approach to backside contact schemes, however, does not support contact jumpers. Backside contact jumpers are beneficial in connecting together several bottom S/D regions to the frontside of the wafer. The exemplary embodiments, by employing a backside contact with a contact jumper or gate jumper, can reduce frontside metal track usage and thus potentially reduce cell height or free up more tracks for global routing. The gate jumpers connect several S/D regions together on the backside of the wafer.

Moreover, the exemplary method includes forming a SiGe etch stop layer under a BDI region of a stacked FET, performing a punch-through the BDI and partially recessing the SiGe etch stop layer, forming Si epi in the recess, forming bottom epi over the Si epi, forming remaining FEOL, MOL, BEOL processes, and a bonding carrier wafer, flipping the wafer, removing the substrate, stopping on the SiGe etch stop, removing the SiGe etch stop selective to Si epi and the BDI, forming backside contacts to expose the Si epi, without touching the BDI, and recessing the Si epi to form backside contacts with jumpers.

Further, the exemplary semiconductor structure includes a first type of backside contact that connects more than one S/D region, with horizontal portions overlapping with the gate. The backside contact is then wired to the frontside BEOL interconnect through a deep via contact. In one instance, there is a second type of backside contact, which wires a S/D region to a backside power rail. In another instance, the first type of backside contact has a shorter height than the second type of the backside contact. In another instance, the semiconductor device is a stacked FET, and the S/D regions are bottom S/D regions.

Regarding FIGS. 1-14, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

Removal is any process that removes material from the wafer: examples include etch processes (either wet or dry), and chemical-mechanical planarization (CMP), etc.

Patterning is the shaping or altering of deposited materials, and is generally referred to as lithography. For example, in conventional lithography, the wafer is coated with a chemical called a photoresist; then, a machine called a stepper focuses, aligns, and moves a mask, exposing select portions of the wafer below to short wavelength light; the exposed regions are washed away by a developer solution. After etching or other processing, the remaining photoresist is removed. Patterning also includes electron-beam lithography.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which usually include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of methods and structures providing for constructing a self-aligned backside contact with a contact jumper for a stacked field effect transistor (FET) (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A semiconductor structure comprising:
backside contacts with jumpers; and
frontside back-end-of-line (BEOL) components electrically connected to the backside contacts by one or more deep via contacts.

2. The semiconductor structure of claim 1, wherein the jumpers electrically connect a plurality of source/drain (S/D) regions.

3. The semiconductor structure of claim 1, wherein at least one of the backside contacts is electrically connected to a backside power rail.

4. The semiconductor structure of claim 1, wherein at least one of the backside contacts is electrically connected to a backside power delivery network (BSPDN).

5. The semiconductor structure of claim 1, wherein at least one of the backside contacts has a first height and at least one of the backside contacts has a second height, where the second height is greater than the first height.

6. The semiconductor structure of claim 1, wherein the jumpers have a substantially convex shape.

7. The semiconductor structure of claim 1, wherein the jumpers are vertically aligned with a plurality of bottom S/D regions and a plurality of top S/D regions.

8. The semiconductor structure of claim 1, wherein the semiconductor structure further includes stacked field effect transistors (FETs).

9. The semiconductor structure of claim 8, wherein the stacked FETs are vertically offset from the jumpers.

10. A semiconductor structure comprising:
stacked field effect transistors (FETs);
backside contacts with jumpers; and
frontside back-end-of-line (BEOL) components electrically connected to the backside contacts by one or more deep via contacts.

11. The semiconductor structure of claim 10, wherein the jumpers electrically connect a plurality of source/drain (S/D) regions.

12. The semiconductor structure of claim 10, wherein at least one of the backside contacts is electrically connected to a backside power rail.

13. The semiconductor structure of claim 10, wherein at least one of the backside contacts is electrically connected to a backside power delivery network (BSPDN).

14. The semiconductor structure of claim 10, wherein at least one of the backside contacts has a first height and at least one of the backside contacts has a second height, where the second height is greater than the first height.

15. The semiconductor structure of claim 10, wherein the jumpers have a substantially convex shape.

16. The semiconductor structure of claim 10, wherein the jumpers are vertically aligned with a plurality of bottom S/D regions and a plurality of top S/D regions.

17. The semiconductor structure of claim 10, wherein the stacked FETs are vertically offset from the jumpers.

18. A method comprising:
forming a stacked field effect transistor (FET) over an etch stop layer placed over a substrate;
recessing the etch stop layer to define trenches between the stacked FETs;
depositing bottom epitaxial growth within the trenches;
forming bottom source/drain (S/D) epi over the bottom epitaxial growth;
forming top S/D epi over the bottom S/D epi;
constructing remaining front-end-of-line (FEOL), middle-of-line (MOL), and back-end-of-line (BEOL) components;
bonding a carrier wafer to the BEOL;
flipping the wafer;
removing the substrate and removing the etch stop layer selective to the bottom epitaxial growth;
depositing an interlayer dielectric (ILD); and
forming backside contacts with jumpers such that the BEOL components electrically connect to the backside contacts by one or more deep via contacts.

19. The method of claim 18, wherein the jumpers electrically connect a plurality of source/drain (S/D) regions.

20. The method of claim 18, wherein at least one of the backside contacts is electrically connected to a backside power rail.
